(19) United States
(12) Patent Application Publication
(10) Pub. No.: US 2025/0154683 A1
(43) Pub. Date: May 15, 2025

(54) A NOVEL HIGH-PERFORMANCE PHOTODETECTOR BASED ON TWO-DIMENSIONAL PEROVSKITE CRYSTALS WITH ALTERNATING INTERLAYER CATIONS

(71) Applicant: City University of Hong Kong, Hong Kong (HK)

(72) Inventors: Johnny Chung Yin HO, Hong Kong (HK); Yezhan LI, Hong Kong (HK); You MENG, Hong Kong (HK); Zhengxun LAI, Hong Kong (HK); Quan QUAN, Hong Kong (HK)

(21) Appl. No.: 18/631,022

(22) Filed: Apr. 9, 2024

Related U.S. Application Data
(60) Provisional application No. 63/597,347, filed on Nov. 9, 2023.

(51) Int. Cl. C30B 29/12; C30B 7/14

(52) U.S. Cl. CPC C30B 29/12; C30B 7/14

(57) ABSTRACT

In this invention, a high-performance photodetector based on 2D bilayered hybrid lead halide perovskite single crystal with ACI phase, with a chemical formula of GAMA₂Pb₂I₇ where GA is C(NH₂)₃ and MA is CH₃NH₃,) was fabricated, using a facile and cost-effective method based on cooling crystallization. The single-crystal photodetector exhibits high photoresponsivity, together with correspondingly high detectivity values. Meanwhile, a high-resolution imaging sensor is built based on the GAMA₂Pb₂I₇ single-crystal photodetector, confirming the high stability and photosensitivity of the imaging system.

### CROSS-REFERENCE TO RELATED APPLICATIONS

The present application claims priority from a U.S. provisional patent application Ser. No. 63/597,347 filed Nov. 9, 2023, and the disclosure of which are incorporated by reference in their entirety.

### FIELD OF THE INVENTION

The present invention generally relates to the field of photodetectors. More specifically, the present invention relates to a photodetector with enhanced performance, based on 2D bilayered hybrid lead halide perovskite single crystal with ACI phase.

### BACKGROUND OF THE INVENTION

Photodetectors (PDs), which can directly convert optical signals into electrical signals, play a significant part in imaging, security systems, industrial inspection, and so on. To fabricate high-performance PDs, a semiconductor with a good ability to absorb incident photons and then produce photogenerated carriers effectively is indispensable. So far, various types of semiconductors, including silicon, group II-VI compounds, group III-V compounds, and organics, have been extensively explored for use in PDs.

However, these semiconductor materials usually require relatively complicated and expensive ways to synthesize, in which the epitaxy and vapor-liquid-solid (VLS) mechanisms are usually involved. Thus, it is urgent to discover new promising candidates to further design the photodetector with high performance, low cost, and case of fabrication.

Recently, the three-dimensional (3D) organic-inorganic hybrid lead halide perovskites in the forms of CH₃NH₃PbX₃ (X=I, Br, Cl) have received intense attention owing to their low-cost fabrication and excellent optoelectronic properties. As a result, they have impressive developments, especially in the high-efficient perovskite solar cells. To date, a certified photovoltaic power conversion efficiency (PCE) of hybrid perovskite solar cells has approached 25.7% (until March. 2023), which is higher than that of many reported conventional thin-film solar cells, organic photovoltaics, and dye-sensitized solar cells.

Moreover, this kind of material with excellent features has also attracted enormous attention in other optoelectronic devices, such as lasers, transistors, and light-emitting diodes (LEDs). Especially, perovskites have been examined for high-performance wide-spectrum photodetection from X-ray, UV, visible, to near-infrared light. However, the poor stability of these 3D perovskite-based devices hinders their further commercial applications.

Using short alkyl ammonium or aromatic ammonium cations to low-dimensional perovskites is an effective method to balance device stability and performance. Based on this route, plenty of perovskites with different dimensions, including zero-dimension (OD), one-dimension (1D), and two-dimension (2D), were synthesized. Among them, 2D perovskite shows better optoelectronic performance when compared with OD and ID perovskite due to their layered structure being analogue to the conventional 3D perovskites.

From a structural perspective, 2D layered hybrid perovskites could be classified into three types: Dion-Jacobson (DJ), Ruddlesden-Popper (RP), and the newly discovered alternating cations in the interlayer (ACI) types. The 2D ACI perovskite described by the formula (C(NH₂)₃) (CH₃NH₃)ₙPbₙI₃ₙ₊₁, featuring two different alternating organic cations in the interlayer space, was recently presented.

Compared to the more common DJ-phase and RP-phase layered hybrid perovskites, the perovskite with ACI phase adopts the short organic cations between inorganic layers, which decrease the bandgap and exciton binding energy, being favorable for the performance improvement of optoelectronic devices. For example, a stable 2D ACI perovskite solar cells is reported with superior PCE exceeding 19.00%. In addition, a LED made of the ACI perovskites was successfully fabricated, showing an external quantum efficiency (EQE) of 3.4% under high current density. In this regard, the 2D hybrid perovskites with ACI phase possess great potential for manufacturing high-performance photodetection with improved stability.

### SUMMARY OF THE INVENTION

In view of the immense potential in the use of two-dimensional hybrid perovskites with ACI phase for high-performance photodetection, the present invention discloses a facile and cost-efficient method of synthesizing a novel 2D bilayered lead-halide hybrid perovskite single crystals with ACI phase, which has a chemical formula of GAMA₂Pb₂I₇, where GA is C(NH₂)₃ and MA is CH₃NH₃, based on a cooling crystallization method.

In accordance with a first aspect of the present invention, the method of synthesizing the two-dimensional lead-halide hybrid perovskites perovskite single crystals comprises adding a guanidine salt, a methylamine component and a lead salt into a solution of hypophosphorous acid (H₃PO₂) water solution and hydroiodic acid (HI). The mixture is subsequently heated to a temperature of 220° C. to 240° C. and stirring to remove all precipitation, stirred to remove all precipitation, and cooled to a room temperature of 15° C. to 25° C., where the saturated solution is cooled and desired crystals are formed by crystallization and obtained, with a yield of at least 70% relative to Pb.

In one embodiment of the first aspect of the invention, the guanidine salt is selected from guanidine carbonate, guanidine hydrochloride, guanidinium bromide, guanidinium iodide or guanidine phosphate, or any combinations thereof.

In another embodiment, the methylamine component is selected methylamine, methylamine hydrochloride, methylammonium bromide, or any combinations thereof.

In other embodiment, the lead salt is selected from lead carbonate, lead iodide, lead bromide, lead chloride, lead (II) acetate trihydrate, or any combinations thereof.

In an embodiment of the first aspect of the invention, the molar ratio of guanidine salt, lead salt and methylamine component is selected from a range of 1:1.5:1.5 to 1:2.5:2.5.

In another embodiment, the speed of cooling the mixture from a temperature of 65° C. to 85° C. to room temperature of 15° C. to 25° C. is 0.5° C./day to 2° C./day.

A photodetection device is also provided herewith, comprising the 2D bilayered lead-halide hybrid perovskite single crystals of GAMA₂Pb₂I₇, disposed on a substrate and having electrodes formed thereon.

In an embodiment of the second aspect of the invention, the electrodes are deposited on the two-dimensional bi-layered lead-halide hybrid perovskite single crystals with ACI phase by a high-vacuum thermal evaporator at a thickness of 45 nm to 55 nm.

In a further embodiment, the electrodes comprise gold (Au).

In other embodiment, the substrate is selected from glass, ceramic, polymer, semiconductor or any combination thereof.

In another embodiment, the photoresponsivity of the device is at least 1.50 A/W under an incident light with a wavelength of 400 nm to 700 nm.

In yet another embodiment, the detectivity of the device is at least 1.50×10¹² Jones under an incident light with a wavelength of 400 nm to 700 nm.

### BRIEF DESCRIPTIONS OF DRAWINGS

FIG. 1A shows the 2D bilayered crystal structures of GAMA₂Pb₂I₇. All hydrogen atoms are omitted. FIG. 1B shows the crystal structure viewed along the c-axis direction. FIG. 1C illustrates the powder XRD pattern and simulated XRD pattern of GAMA₂Pb₂I₇.

FIG. 2A shows the absorption spectra of GAMA₂Pb₂I₇ crystals, where the inset is the optical bandgap obtained by the Tauc plot method. FIG. 2B shows the DFT calculated band structure; and FIG. 2C shows the PDOS spectra of GAMA₂Pb₂I₇.

FIG. 3A is a schematic diagram of GAMA₂Pb₂I₇ photodetector architecture. FIG. 3B illustrates the XRD patterns of bulk single crystal of GAMA₂Pb₂I₇. FIG. 3C shows the normalized responsivity of the corresponding GAMA₂Pb₂I₇ photodetector under the 400-800 nm illumination light. FIGS. 3D, 3E and 3F shows the respective I-V curves of dark current and photocurrent under different incident power levels at −1.5 V (2=405, 532, and 635 nm respectively).

FIGS. 4A to 4I illustrate the performance of the GAMA₂Pb₂I₇ photodetector in the visible light spectrum. FIGS. 4A, 4B and 4C shows the I-T curves, photocurrent (Iₚₕ), responsivity (R), detectivity (D) and EQE under illumination wavelengths of 405 nm. FIGS. 4D, 4E and 4F shows the I-T curves, photocurrent (Iₚₕ), responsivity (R), detectivity (D) and EQE under illumination wavelengths of 532 nm. FIGS. 4G, 4H and 4I shows the I-T curves, photocurrent (Iₚₕ), responsivity (R), detectivity (D) and EQE under illumination wavelengths of 635 nm.

FIG. 5A is a schematic diagram of the imaging system based on the GAMA₂Pb₂I₇ photodetector. FIG. 5B shows the corresponding imaging results from the fabricated GAMA₂Pb₂I₇ image sensor under a 532 nm laser.

FIG. 6. is a photograph of a GAMA₂Pb₂I₇ single crystal.

FIGS. 7A and 7B show the crystal structure of GAMA₂Pb₂I₇, viewed along the a-axis and b-axis respectively.

FIGS. 8A, 8B and 8C show the XPS results of the GAMA₂Pb₂I₇ single crystal.

FIGS. 9A to 9C are time-resolved high-resolution I-T curves of GAMA₂Pb₂I₇ photodetecor. FIG. 9A shows I-T curves of the GAMA₂Pb₂I₇ photodetector under illumination wavelength of 405 nm. FIG. 9B SHOWS I-T curves of the GAMA₂Pb₂I₇ photodetector under illumination wavelength of 532 nm. FIG. 9C shows I-T curves of the GAMA₂Pb₂I₇ photodetector under illumination wavelength of 635 nm.

FIG. 10 shows the result of a long-term operating test of GAMA₂Pb₂I₇ photodetector under shopped 532 nm laser illumination.

FIG. 11 illustrates the thermogravimetric analysis of GAMA₂Pb₂I₇ crystal.

FIG. 12 shows the recorded spatially resolved photocurrent of GAMA₂Pb₂I₇ photodetector.

### DETAILED DESCRIPTION

The present invention provides a method of synthesizing a novel two-dimensional bi-layered lead-halide hybrid perovskite single crystals with ACI phase, wherein the chemical formula of the two-dimensional bi-layered lead-halide hybrid perovskite single crystals with ACI phase is GAMA₂Pb₂I₇, (where GA is C(NH₂)₃ and MA is CH₃NH₃). The two-dimensional bi-layered lead-halide hybrid perovskite single crystals with ACI phase display higher crystal symmetry and narrowed bandgaps, which has a great potential in significant enhancement in photodetection performance.

ACI-phase perovskites have the formula R′AₙBₙX₃ₙ₊₁, where the smaller cation R also fills the interlayer with another bulky ‘R’ cation. Most ACI-phase perovskites are formed by incorporating guanidinium (GUA⁺) and MA⁺ cations. The ACI-phase perovskite has an unprecedented structure that can be viewed as blending the chemical formula of the RP-phase perovskite with the structural features of the DJ-phase perovskite. Compared with the common RP-phase perovskites, ACI-phase perovskites have a different stacking motif and adopt a higher crystal symmetry, with a slightly narrower bandgap. As direct bandgap semiconductors are with wide valence and conduction bandwidths, ACI-phase perovskites show promising potential for photovoltaic applications.

Specifically, the synthesis method is based on cooling crystallization, which is highly facile in comparison with other existing 2D perovskite crystal synthesis methods, while maintaining a reasonably high yield of no lower than 70% in relation to Pb.

In addition, a photodetection device comprising the novel two-dimensional bi-layered lead-halide hybrid perovskite single crystals with ACI phase is also disclosed herewith, with a structure of Au/GAMA₂Pb₂I₇/Au, which exhibits high photoresponsivity and high detectivity values under incident light of wavelengths within the spectrum of visible light, i.e. approximately 400 nm-700 nm.

As the synthesis method of the novel two-dimensional bi-layered lead-halide hybrid perovskite single crystals with ACI phase could be performed with relatively low-cost apparatuses without the requirement of specific or harsh conditions, facile and cost-effective production of the photodetection device is possible.

In accordance with a first aspect of the present invention, the synthesis method involves adding guanidine carbonate salt (GA), methylamine hydrochloride (MA), and lead (II) acetate trihydrate into a solution containing hypophosphorous acid (H₃PO₂) and hydroiodic acid (HI). The resulting mixture undergoes heating to a temperature between 220° C. and 240° C., with continuous stirring to remove all precipitants. Subsequently, the mixture is cooled to room temperature (for example, a temperature range of approximately 15° C. to 25° C.) to obtain the crystallized products. The two-dimensional bi-layered lead-halide hybrid perovskite single crystals with ACI phase, denoted as GAMA₂Pb₂I₇, are formed, where GA represents C(NH₂)₃ and MA represents CH₃NH₃. The yield of these crystals with ACI phase is guaranteed to be at least 70% relative to lead (Pb).

A molar ratio of guanidine carbonate salt, lead (II) acetate trihydrate, and methylamine hydrochloride, may be within a range of 1:1.5:1.5 to 1:2.5:2.5 to optimize the synthesis process.

The cooling process involves a controlled speed from 65° C. to room temperature (15° C. to 25° C.) at 1° C./day, ensuring the gradual formation of the desired crystal structure.

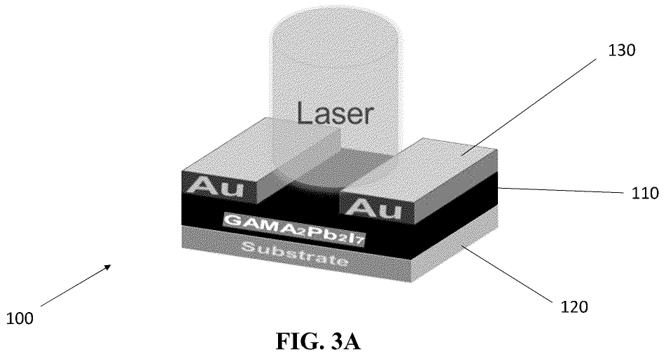

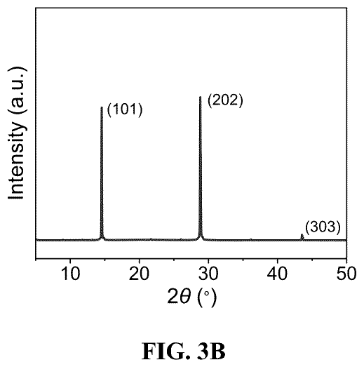

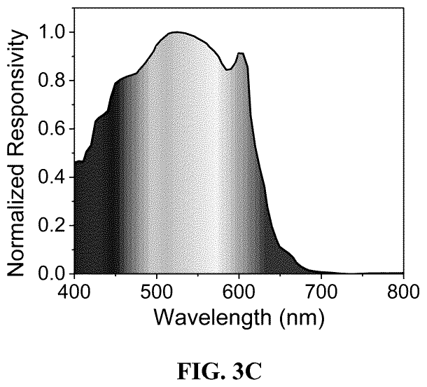

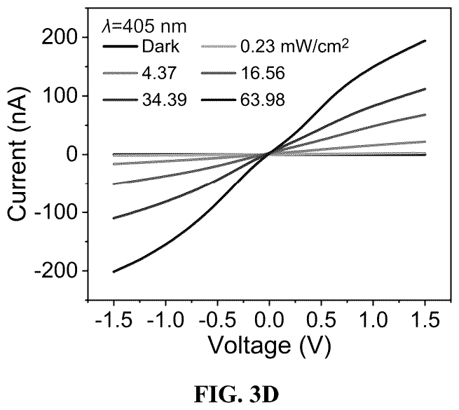

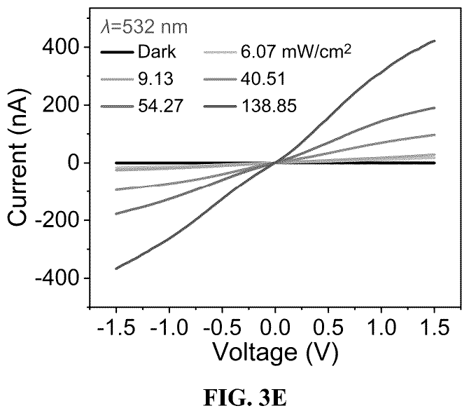

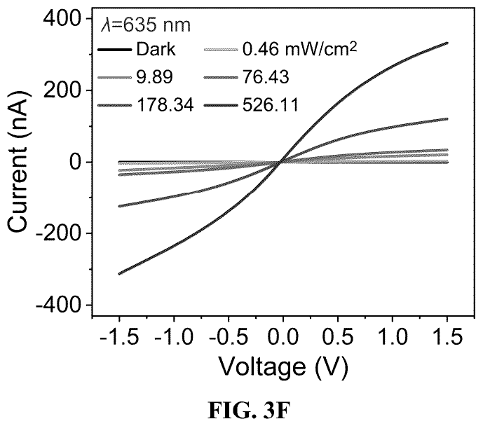

FIG. 3A schematically depicts a photodetection device 100. Device 100 includes a layer 110 of GAMA₂Pb₂I₇ on a substrate such as glass, a ceramic, polymer, or semiconductor substrate 120. Electrodes 130 are formed on the GAMA₂Pb₂I₇ layer. In the embodiment of FIG. 3A, gold electrodes are depicted; however, other conductive electrode materials may be used such as copper and aluminum, transparent electrodes such as indium tin oxide may also be employed. For the gold layer embodiment of FIG. 3A, the gold deposition is performed using a high-vacuum thermal evaporator, achieving a thickness ranging from 45 nm to 55 nm.

The photodetector of FIG. 3A is high photoresponsivity. For example, a minimum photoresponsivity of 1.50 A/W under an incident light with a wavelength of 400 nm to 700 nm and a minimum detectivity of 1.50×10¹² Jones under the same conditions.

The photodetector of FIG. 3A may be employed in a high-resolution imaging system The integration of the FIG. 3A photodetector into such an imaging system ensures the efficient detection of incident light, making the imaging system suitable for high-resolution applications.

### EXAMPLES

### Example 1. Synthesis of GAMA₂Pb₂I₇ crystals

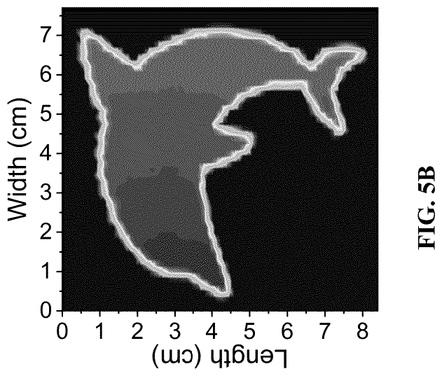

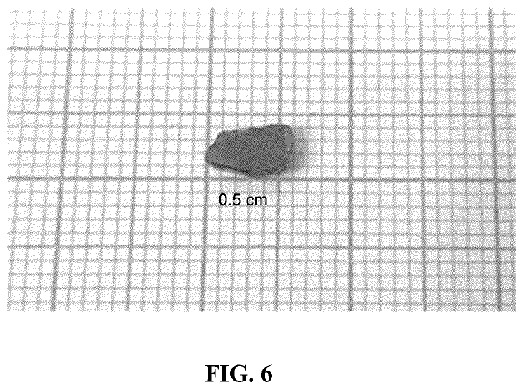

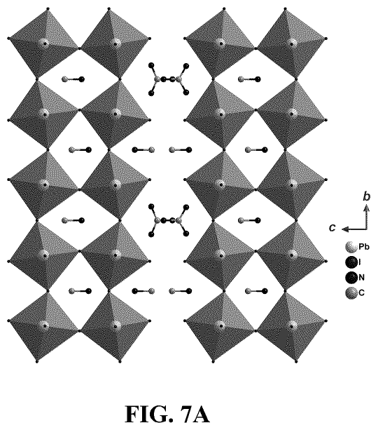

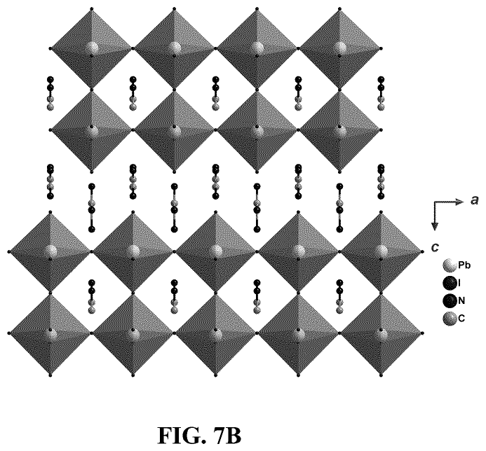

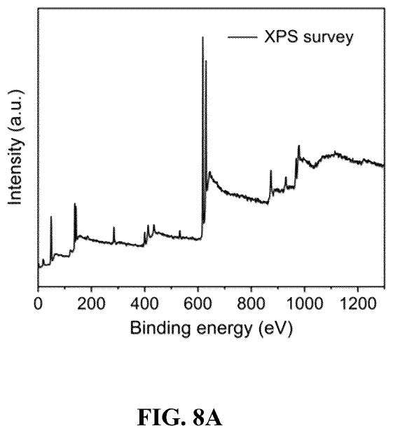

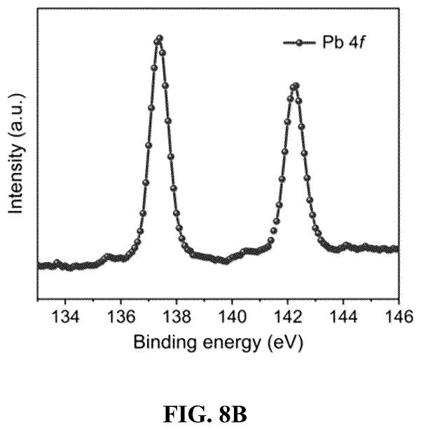

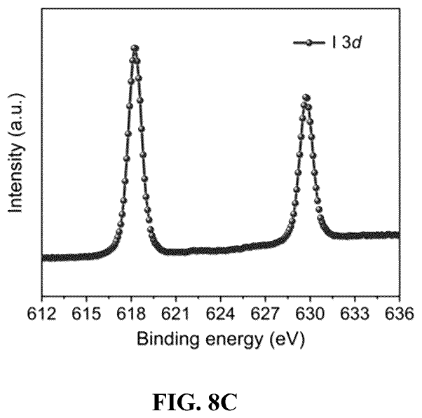

The 2D hybrid perovskite of GAMA₂Pb₂I₇ crystals was synthesized using guanidine carbonate salt (C₂H₁₀N₆·CH₂O₃, 99%, J&K Scientific), lead (II) acetate trihydrate (C₄H₆O₄Pb·₃H₂O, 99%, Sigma-Aldrich), methylamine hydrochloride (CH₅N·HCl, 99%, J&K Scientific), hypophosphorous acid (H₃PO₂, 50% (in mass) water solution, J&K Scientific) and hydroiodic acid (HI, 47%, Macklin). First, 5.4 g (59.5 mmol) guanidine carbonate salt, 4.02 g (30.0 mmol) methylamine hydrochloride, and 22.8 g (60.1 mmol) lead (II) acetate trihydrate were slowly added into a solution of 100 mL hydroiodic acid and 2 mL hypophosphorous acid. After that, a quick stir would mix them thoroughly at a temperature of 230° C. until there is no precipitation. The small GAMA₂Pb₂I₇ powder-like samples would appear when cooling to room temperature (20° C./h) as crystallized products. A yield of 76% was estimated relative to Pb. To allow the growth of crystallized products into the form of bulk perovskite crystals, a constant-speed temperature-programmable bath was used to control the cooling speed. After cooling the bath from 65° C. to room temperature (1° C./d), millimeter-level bulk crystals were obtained (see FIG. 6). The purity of these powder and single crystal samples was confirmed by a D2 PHASER XE-T X-ray Diffractometer System. The absorption spectra were obtained using a UV-3600i Plus UV-VIS-NIR spectrometer.

### Example 2. Device fabrication and characterizations

To fabricate the photodetection device, Au electrodes with a thickness of 50 nm were deposited by a high-vacuum thermal evaporator with an evaporation rate of about 1.8 Å/s. In a shadow masking process, the length and width of the device channel were defined to be 65 μm and 15 μm, respectively. Room temperature I-V and I-T characteristics under different incident light wavelengths (405, 532, and 635 nm) were measured using a semiconductor analyzer (Agilent 4155C). The incident light power was calibrated by PM400, Thorlabs. To obtain the high-speed response time, precisely time-resolved I-T curves of the GAMA₂Pb₂I₇ device were recorded via a digital oscilloscope (Tektronix, TBS 1102B,) connected with a low-noise current preamplifier (Stanford Rescarch Systems, SR570).

### Example 3. Measured Material Properties

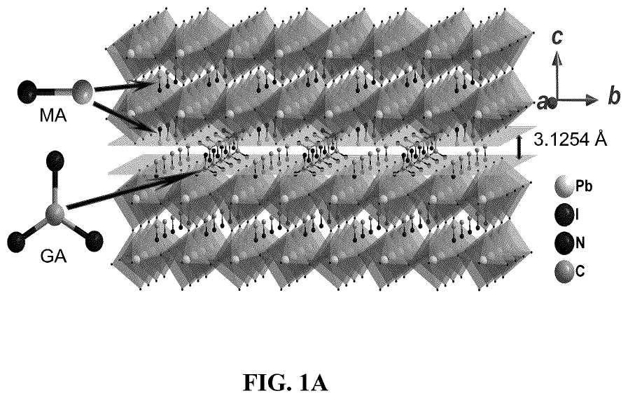

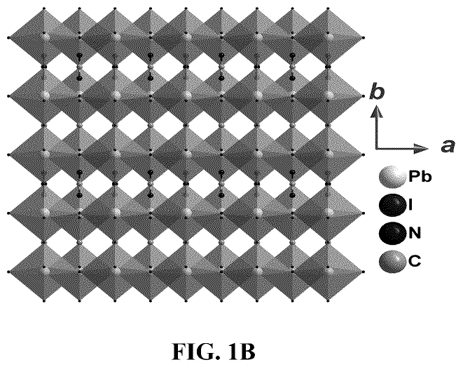

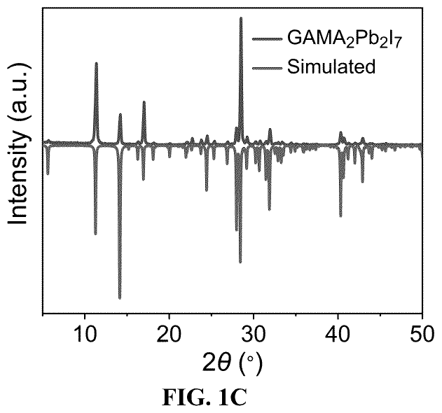

As the photograph shown in FIG. 6, black-color single crystals of GAMA₂Pb₂I₇ were grown from its saturated solution through the cooling crystallization method. The measured PXRD pattern agrees well with the simulation result, which confirms its crystal structure (FIG. 1C). Single-crystal structural analysis discovers that it crystallizes in the space group No. 38, orthorhombic Bmm2 at 293 K. FIG. 1A illustrates 2D ACI perovskite structure, where the layered parts contain corner-sharing [Pb₂I₇]^{∞} bilayers and MA⁺ cations, which pile up along the c-axis. Meanwhile, GA⁺ and interlayer MA⁺ organic cations are ordered packing between the perovskite layers and linked to the infinite bilayered perovskite via N—H···I hydrogen bonds. Especially, due to the small ionic radius of MA (217 pm) and GA (278 pm), the distance between [Pb₂I₇]^{∞} inorganic layers is as short as 3.1254 Å. It is noted that such short interlayer distance has a significant impact on their optoelectronic properties, altering their bandgap and dielectric confinement in 2D hybrid perovskites.

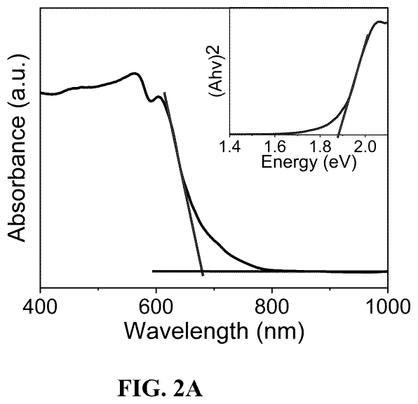

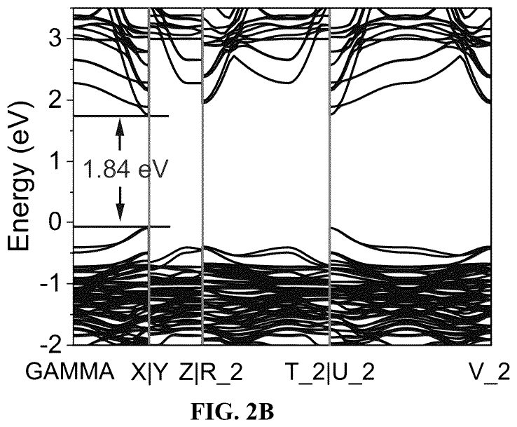

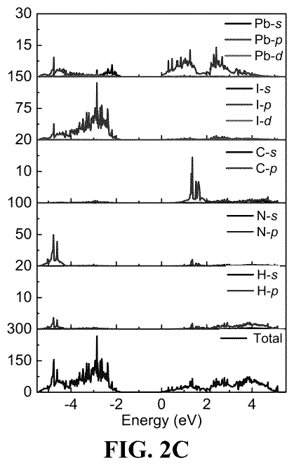

As the ultraviolet-visible absorption spectrum shown in FIG. 2A, the absorption edge at 680 nm indicates that GAMA₂Pb₂I₇ could absorb wide-band visible light. Besides, the optical bandgap is determined by the Tauc plot method, and the estimated value extracted from the Tauc plot is 1.88 eV (the inset of FIG. 2A). Meanwhile, we evaluate the band structures and electronic properties of GAMA₂Pb₂I₇ crystals by using the first-principles density functional theory (DFT). (FIG. 2B). Both the conduction band maximum (CBM) and valence band minimum (VBM) are obviously located at the same point, which confirms that GAMA₂Pb₂I₇ belongs to a kind of direct bandgap semiconductor. The calculated bandgap value of 1.84 eV matches well with the experimental value. Furthermore, the partial density of states (PDOS) spectra demonstrate that the unoccupied I-p orbitals contribute to the VBM, while the Pb-p orbitals contribute to the CBM (FIG. 2C).

Based on the good material properties, single-crystal GAMA₂Pb₂I₇ photodetectors were constructed using Au as electrodes and glass as a substrate, where the planar device configuration is shown in FIG. 3A. The detailed device fabrication processes were displayed in the experimental section. As the photodetector was made by bulk perovskite single crystal, the crystal anisotropy needs to be taken into consideration. As shown in FIG. 3B, the XRD pattern of the single crystal GAMA₂Pb₂I₇ exhibits periodically repeated diffraction peaks corresponding to the (101) plane group, demonstrating the high degree of orientation of the formed GAMA₂Pb₂I₇ single crystal.

First, the spectral response of single-crystal GAMA₂Pb₂I₇ was measured with wavelength ranging from 400 nm to 800 nm under an applied voltage of −1.5 V bias (FIG. 3C). The photoresponsivity shows a wide-spectrum response with a cutoff wavelength close to 700 nm, which is consistent with the absorption spectra presented in FIG. 2A. After that, three different incident light wavelengths of 405, 532, and 635 nm were used to characterize the photodetection performance of the GAMA₂Pb₂I₇ photodetector. The current-voltage (I-V) curves in the dark and under different illumination light intensities were recorded with a bias voltage of −1.5 V (FIGS. 3D-3F). The current increased dramatically when the device was illuminated by increasing light intensity. This phenomenon could be attributed to the stronger illumination, which will generate more photogenerated carriers and flow through the channel, causing higher photocurrent in the circuit.

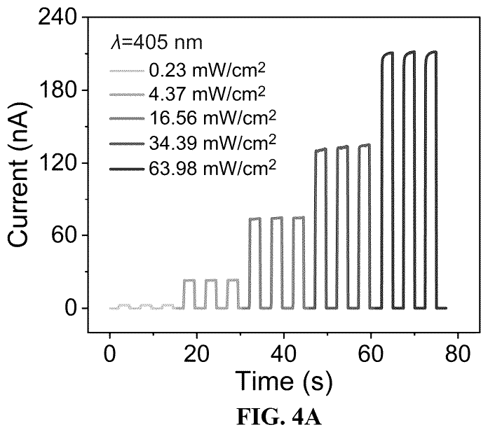

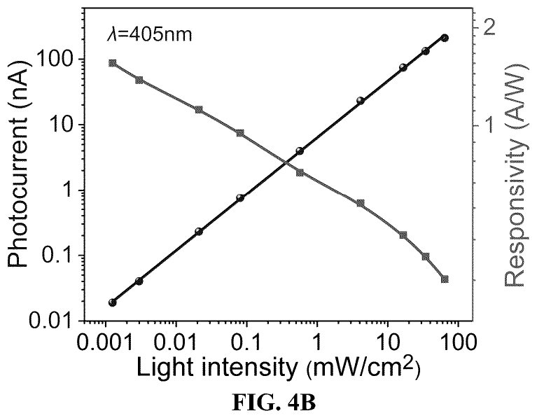

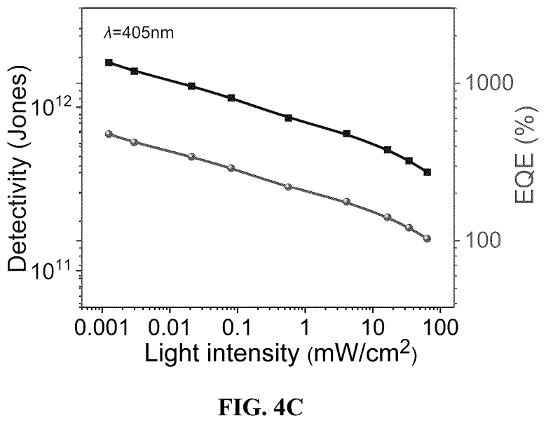

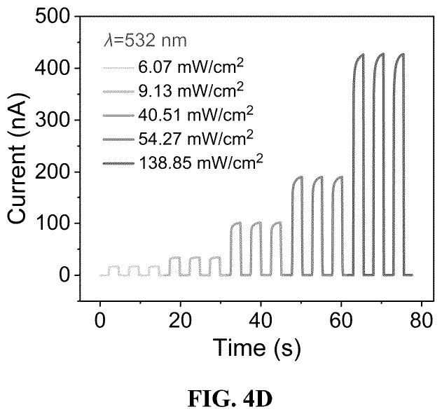

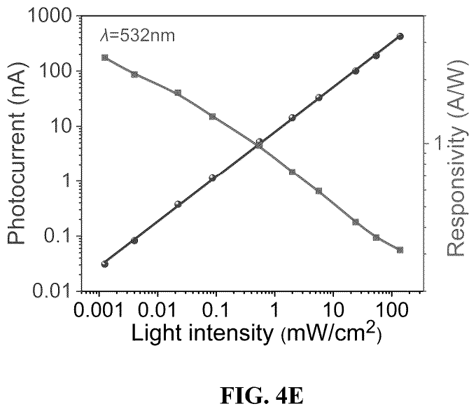

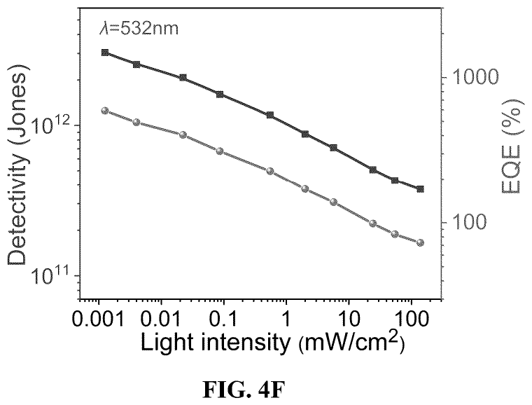

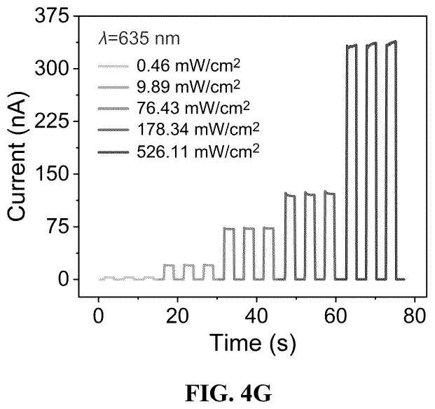

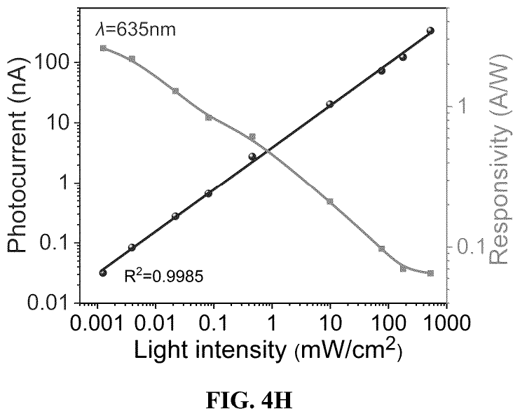

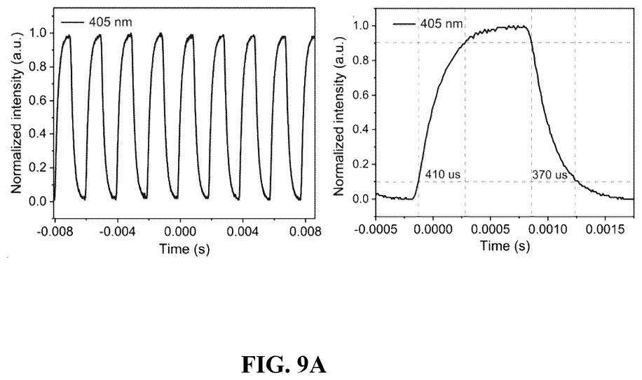

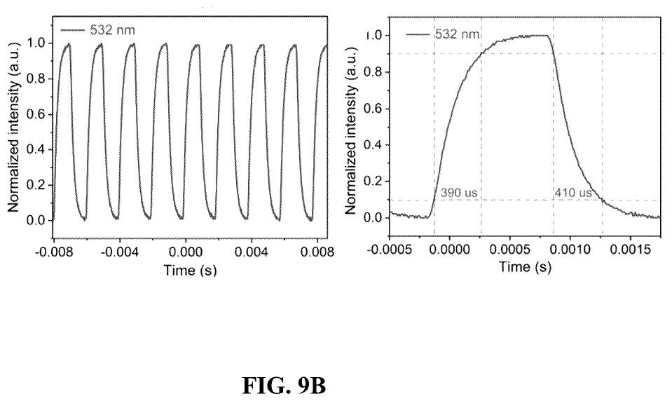

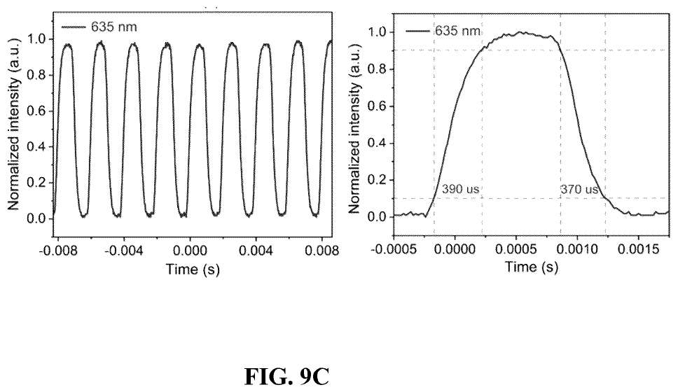

At the same time, the I-T curves of the GAMA₂Pb₂I₇ PDs were also recorded under different illumination of 405 nm, 532 nm, and 635 nm laser at −1.5 V (FIGS. 4A, 4D, and 4G). The measured current shows reproducible on-off switching behaviors under different incident wavelengths and different light illumination powers. The time-resolved I-T curves of PDs were measured by a high-speed photoresponse measurement circuit, by which the rise and decay times could be estimated from the precise photoresponse signals. The rise time is defined from 10% to 90%, and the decay time is estimated from 90% to 10% of the output signal maximum. As a result, both the rise and decay times are approximately 400 us, though with different incident light wavelengths, suggesting the fast response of the device (FIGS. 9A-9C).

To understand the photoresponse behaviors, the incident light power versus photocurrent Iₚₕ (Iₚₕ=Iₒₙ−I_{dark}) is compiled under the illumination of different wavelength light (FIGS. 4B, 4E, 4H), in which the relationship can be fitted by the formula 1:

$${I}_{ph} = {AP}^{x} \qquad ( 1 )$$

where P represents the photocurrent, while x and A mean the fitting exponent and the scaling constant, respectively. Through fitting, the Iₚₕ shows a power dependence of 0.86, 0.81, and 0.70 under 405, 532, and 635 nm incident light. Such sublinear correlation between the Iₚₕ and the incident light intensity can be attributed to the intricate mechanisms involving exciton generation, trapping, and recombination, which are commonly witnessed in semiconducting materials.

Besides, to further evaluate the photodetection performance of the GAMA₂Pb₂I₇ photodetector, the responsivity (R), detectivity (D*), and EQE were obtained by the following formulas:

$$R = \frac{{I}_{ph}}{Ps} \qquad ( 2 )$$

$${D}^{*} = R \sqrt{\frac{S}{2 {qI}_{dark}}} \qquad ( 3 )$$

$$EQE = \frac{hcR}{q λ} \qquad ( 4 )$$

where S is the active area of the photodetector, q is the absolute value of electron charge (1.6×10⁻¹⁹ C), I_{dark} represents the dark current, h represents the Planck's constant, c means the velocity of light, and λ represents the incident wavelength. The light intensity-dependent R of the device under illumination with different light intensities were measured, as depicted in FIGS. 4B, 4E, and 4H. The high photoresponsivity of 1.56, 2.54, and 2.60 A/W could be achieved for the GAMA₂Pb₂I₇ photodetector under 405, 532, and 635 nm incident light under 9.82 nW, respectively, which is larger than that of most reported 2D RP and DJ hybrid perovskite single-crystal photodetectors, as tabulated in Table 1 below.

TABLE 1

| | | | | Rise/decay | |
|---|---|---|---|---|---|
| | Wavelength | Responsivity | Detectivity | time | Continuous |
| Material | (nm) | (A/W) | (Jones) | (μs) | irradiation test |
| GAMA₂Pb₂I₇ | 405 nm | 1.56 | 1.86 × 10¹² | 410/370 | Maintained |
| single crystal | 532 nm | 2.54 | 3.04 × 10¹² | 390/410 | 85.5% after |
| | 635 nm | 2.60 | 3.11 × 10¹² | 390/370 | 1000 s |
| (BA)₂(MA)₂Pb₃Br₁₀ | 420 | — | 3.6 × 10¹⁰ | 150/570 | — |
| single crystal | | | | | |
| (PEA)₂PbBr₄ | 365 | 3.148 × 10⁻² | 1.55 × 10¹³ | 410/370 | No significant |
| single crystal | | | | | degradation |
| | | | | | after 1000 s |
| (BPA)₂PbBr₄ | 377 | 10⁻⁴ | 10⁷ | 27/30 | — |
| Single crystal | | | | | |
| BDAPbI₄ | 462 | 9.27 × 10⁻¹ | 1.23 × 10¹¹ | 187/163 | Maintained |
| Single crystal | | | | | 96% after |
| | | | | | 250 s |
| (2meptH₂)(MA)Pb₂I₇ | 405 | 13 | — | 40/— | — |
| single crystal | | | | | |
| (HDA)CsPb₂Br₇ | 405 | 8.2 × 10⁻⁵ | 8.1 × 10⁸ | 200/300 | — |
| single crystal | | | | | |
| (GA)(FA)PbI₄ | 515 | 10⁻¹ | 2 × 10¹⁰ | 490/700 | — |
| single crystal | | | | | |

Furthermore, the D* and EQE under different light intensities were calculated and shown in FIGS. 4C, 4F, and 4I. The largest D* for the photodetectors under 405 nm, 532 nm, and 635 nm incident light is 1.86×10¹², 3.04×10¹², and 3.11×10¹² Jones and the corresponding EQE values are up to 477%, 592% and, 508%, respectively.

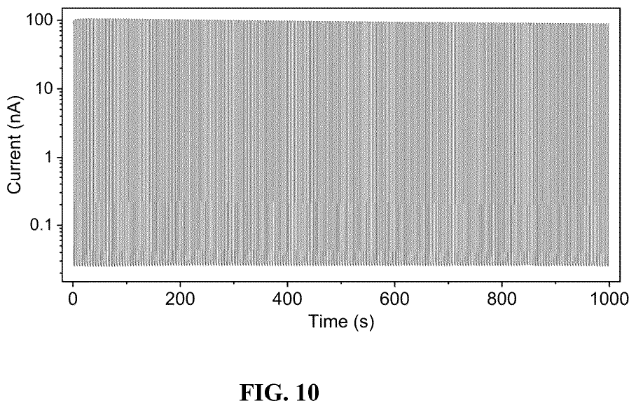

Moreover, the stability of organic-inorganic hybrid perovskite is essential for practical application. FIG. 10 shows the I-T curve of the GAMA₂Pb₂I₇ photodetector under 532 nm laser illumination in the ambient temperature (relative humidity is about 68%). The photocurrent maintained 85.5% of the initial performance after 1000 s operating durations.

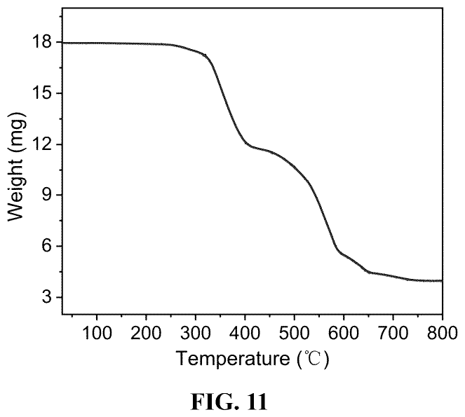

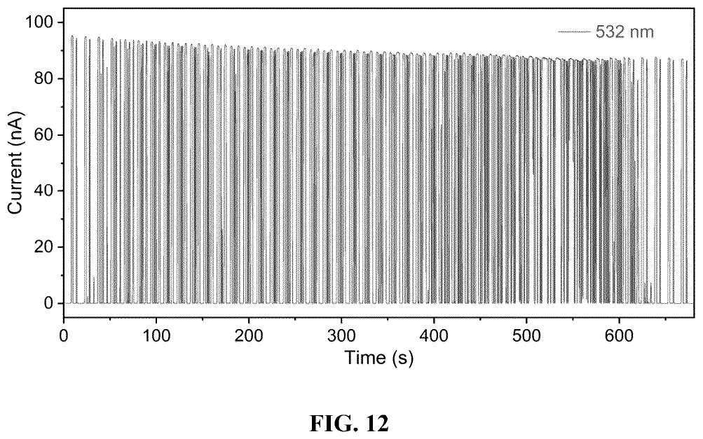

The thermogravimetric analysis curve also shows high thermal stability up to 260° C. (FIG. 11). These results highlight the operation and thermal stability of the GAMA₂Pb₂I₇ crystals, which is beneficial to further practical utilizations.

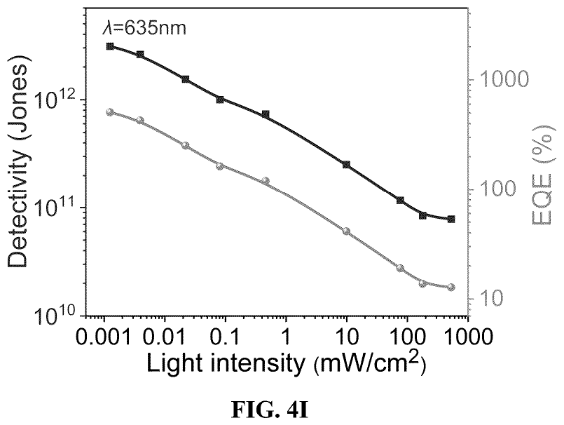

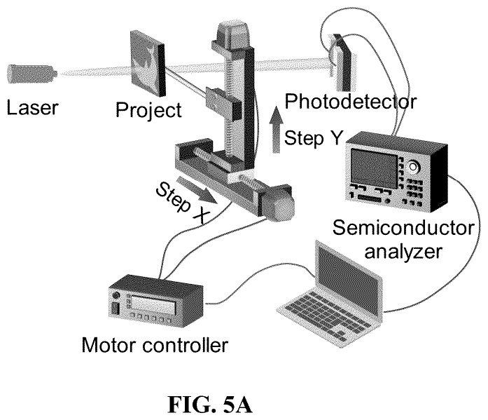

Based on the outstanding photosensitivity in the visible light region, the GAMA₂Pb₂I₇ photodetector holds excellent potential for imaging applications. Herein, a high-resolution imaging system is built based on the GAMA₂Pb₂I₇ photodetector. As shown in FIG. 5A, a laser with a wavelength of 532 nm was used to illuminate the imaging project (a hollow dolphin pattern), which can move sequentially along the X and Y directions. The GAMA₂Pb₂I₇ imaging sensor connected with a semiconductor analyzer was used to record the spatially resolved photocurrent. As a result, a high-resolution dolphin image could be extracted from the recorded photocurrent signal (FIG. 5B), showing the imaging system's good stability and light sensitivity. The above verifies the promising applications in the imaging system based on 2D bilayered hybrid perovskite with ACI phase.

It should be understood that the examples and embodiments described herein are for illustrative purposes only and that various modifications or changes in light thereof will be suggested to persons skilled in the art and are to be included within the spirit and purview of this application.

All patents, patent applications, provisional applications, and publications referred to or cited herein are incorporated by reference in their entirety, including all figures and tables, to the extent they are not inconsistent with the explicit teachings of this specification.

It should be understood that numerous specific details, relationships, and methods are set forth to provide a full understanding of the invention. One having ordinary skill in the relevant art, however, will readily recognize that the invention can be practiced without one or more of the specific details or practiced with other methods, protocols, reagents, cell lines and animals. The present invention is not limited by the illustrated ordering of acts or events, as some acts may occur in different orders and/or concurrently with other acts or events. Furthermore, not all illustrated acts, steps or events are required to implement a methodology in accordance with the present invention. Many of the techniques and procedures described, or referenced herein, are well understood and commonly employed using conventional methodology by those skilled in the art.

Unless otherwise defined, all terms of art, notations and other scientific terms or terminology used herein are intended to have the meanings commonly understood by those of skill in the art to which this invention pertains. In some cases, terms with commonly understood meanings are defined herein for clarity and/or for ready reference, and the inclusion of such definitions herein should not necessarily be construed to represent a substantial difference over what is generally understood in the art. It will be further understood that terms, such as those defined in commonly used dictionaries, should be interpreted as having a meaning that is consistent with their meaning in the context of the relevant art and/or as otherwise defined herein.

1. A method of synthesizing two-dimensional bi-layered lead-halide hybrid perovskite single crystals with ACI (alternating cations in the interlayer) phase, comprising:
adding a guanidine salt, a methylamine component and a lead salt into a solution of hypophosphorous acid (H₃PO₂) water solution and hydroiodic acid (HI);
heating the mixture to a temperature of 220° C. to 240° C. and stirring to ensure a mixture of starting materials without precipitation; and
cooling the mixture to a temperature of 15° C. to 25° C. to obtain a crystallized product;
wherein the crystallized product is a two-dimensional bi-layered lead-halide hybrid perovskite single crystal having a chemical formula of GAMA₂Pb₂I₇, wherein GA is C(NH₂)₃ and MA is CH₃NH₃ and;
wherein the yield of the two-dimensional bi-layered lead-halide hybrid perovskite single crystal product with ACI phase is at least 70% relative to Pb.

2. The method of claim 1, wherein the guanidine salt is selected from guanidine carbonate, guanidine hydrochloride, guanidinium bromide, guanidinium iodide or guanidine phosphate, or any combinations thereof.

3. The method of claim 1, wherein the methylamine component is selected methylamine, methylamine hydrochloride, methylammonium bromide, or any combinations thereof.

4. The method of claim 1, wherein the lead salt is selected from lead carbonate, lead iodide, lead bromide, lead chloride, lead (II) acetate trihydrate, or any combinations thereof.

5. The method according to claim 1, where the molar ratio of guanidine salt, lead salt and methylamine component is selected from a range of 1:1.5:1.5 to 1:2.5:2.5.

6. The method according to claim 1, wherein speed of cooling the mixture from a range of 65° C. to 85° C. to room temperature of 15° C. to 25° C. is 0.5° C./day to 2° C./day.

7. A photodetection device comprising the two-dimensional bi-layered lead-halide hybrid perovskite single crystals formed by the method of claim 1, disposed on a substrate and having electrodes formed thereon.

8. The photodetection device of claim 7, wherein the electrodes are deposited onto the two-dimensional bi-layered lead-halide hybrid perovskite single crystals by a high-vacuum thermal evaporator at a thickness of 45 nm to 55 nm.

9. The photodetection device of claim 7, wherein the electrodes comprise gold.

10. The photodetection device of claim 7, wherein the substrate is selected from ceramic, glass, polymer, semiconductor, or any combinations thereof.

11. The photodetection device of claim 7, wherein the photoresponsivity of the device is at least 1.50 A/W under an incident light with a wavelength of 400 nm to 700 nm.

12. The photodetection device of claim 7, wherein the detectivity of the device is at least 1.50×10¹² Jones under an incident light with a wavelength of 400 nm to 700 nm.
